(19) United States
(12) Patent Application Publication
(10) Pub. No.: US 2021/0305782 A1
(43) Pub. Date: Sep. 30, 2021

(54) INTRACAVITY CONTACT VCSEL STRUCTURE AND METHOD FOR FORMING THE SAME

(71) Applicant: Array Photonics, Inc., Tempe, AZ (US)

(72) Inventor: Radek ROUCKA, East Palo Alto, CA (US)

(21) Appl. No.: 17/207,015

(22) Filed: Mar. 19, 2021

Related U.S. Application Data
(60) Provisional application No. 62/994,528, filed on Mar. 25, 2020.

(51) Int. Cl. H01S 5/183

(52) U.S. Cl. CPC H01S 5/18341; H01S 5/18313

(57) ABSTRACT

A VCSEL device has at least one intracavity contact interleaved with oxidation trenches is disclosed. Interleaving the electrical contacts with the trenches reduces the lateral carrier transport length for current injection associated with the use of an intracavity contact, thereby reducing lateral resistance, while allowing short oxidation times and short oxidation lengths to form the VCSEL confinement structure.

### CROSS-REFERENCE TO RELATED APPLICATION

This application claims the benefit of U.S. Provisional Application No. 62/994,528, filed Mar. 25, 2020, the contents of which are incorporated herein by reference in the entirety for all purposes.

### FIELD OF THE DISCLOSURE

The present disclosure relates to vertical-cavity surface-emitting lasers (VCSELs) and arrays of VCSELs. More particularly, this disclosure relates to intracavity contact VCSELs and intracavity contact VCSEL arrays configured to have reduced oxidation lengths that enable more reliable processing (including reduced diffusion-limited processing effects) and reduced lateral conduction lengths, thereby causing a reduction in lateral resistance associated with the intracavity contacts.

### BACKGROUND

VCSELs have many applications and offer various advantages when compared to edge-emitting lasers. The planar structure of VCSELs, configured to provide light emission propagating along an axis that is transverse to the layers of the planar semiconductor structure, allows on-wafer testing (before dicing and packaging of individual devices or arrays); the ability to form both one-dimensional and two-dimensional arrays; low divergence output beams that facilitate efficient coupling of laser output to the optical fibers, waveguides, and other optical elements; compatibility with traditional low-cost light emitting diode (LED) packaging technology; as well as freedoms of integration with electronic, optoelectronic, and optical elements, high reliability, and high operational efficiency.

The successful use of VCSELs and VCSEL arrays (individually and/or aggregately referred to herein as VCSEL devices) has been demonstrated in optical-fiber-based data and telecommunication applications (typically over shorter distances of about 1 mile or less, such as in local area networks and data centers, for example). VCSEL devices are now finding use in a variety of other applications including free-space optical interconnects, sensors, and illumination sources for systems such as three-dimensional cameras or gesture recognition systems, dot projectors for structured-light sources, and automotive light detection and ranging (LiDAR) applications. These VCSEL devices typically operate at wavelengths of about 850 nm (which light output is produced using gallium arsenide (GaAs) quantum-well (QW) active regions), wavelengths between about 940 nm and 980 nm (where indium gallium arsenide (InGaAs) QW active regions are employed), and more recently, wavelengths between about 1250 nm and 1600 nm (where the devices are structured to utilize dilute nitride QW active regions).

For applications at wavelengths between about 1250 nm and 1600 nm, the free-carrier absorption associated with doping throughout the VCSEL structure increases losses within the device, thereby reducing the emitted power. The increase in free-carrier absorption is particularly important with respect to p-type dopants (the absorption cross-section, which can be larger than that of n-type dopants and can increase faster with higher wavelength operation of the VCSEL devices). In some VCSEL devices, intracavity contacts may be used instead of contacts disposed on the top and/or the bottom of a given device. The intracavity contacts are formed on thin heavily-doped material layers that are designed to minimize optical losses within the device, the majority of the mirror structures can remain undoped. In conventional VCSEL devices, the use of intracavity contacts requires the presence of a longer horizontal conduction path. The placement/location of the contacts with respect to a device aperture may be limited by the size of the mesa etches that are required to form the device and achieve oxidation. Furthermore, as is well recognized in related art, two separate mesa structures of different lateral dimensions are required to produce two intracavity contacts. Consequently, the intracavity contacts are offset from the VCSEL aperture, and such geometry can and often does increase lateral electrical resistance of the device (that is, the resistance in a plane substantially parallel to material layer(s) of the device), thereby affecting carrier injection into the device.

While designs and methods directed at improvement of performance of intracavity contacts are described, for example, in U.S. Pat. No. 6,653,158, issued Nov. 25, 2003, these devices have laterally-offset intracavity contacts.

Therefore, there remains a need to reduce the lateral offset of the intracavity contact(s) from the structural mesa in order to obtain VCSEL devices with reduced (in comparison with existing implementations) lateral conduction length and any associated resistance. The intracavity contacts may allow the VCSEL devices to have current injection at locations closer (as close as possible) to the VCSEL aperture.

### BRIEF DESCRIPTION OF THE DRAWINGS

The following description is made in reference to the drawings that are used for illustration of examples of the disclosed implementations, that are generally not to scale, and are not intended to limit the scope of the present disclosure.

FIG. 1 shows a schematic cross-section of VCSEL epitaxial layers formed on a substrate.

FIG. 2 is a schematic cross section showing a first processing step to fabricate a VCSEL, according to some embodiments of the disclosure.

FIG. 3A is a schematic cross section showing a second processing step to fabricate a VCSEL, according to some embodiments of the disclosure.

FIG. 3B is a schematic cross section showing a third processing step to fabricate a VCSEL, according to some embodiments of the disclosure.

FIG. 4A is a top view of the structure shown in FIG. 3A.

FIG. 4B is a top view of the structure shown in FIG. 3B.

FIG. 5 is a schematic cross section showing a fourth processing step to fabricate a VCSEL, according to some embodiments of the disclosure.

FIG. 6 shows a top view of the structure shown in FIG. 5.

FIG. 7A is a schematic cross section showing a fifth processing step to fabricate a top-emitting VCSEL, according to some embodiments of the disclosure.

FIG. 7B is a schematic cross section showing a fifth processing step to fabricate a bottom-emitting VCSEL, according to some embodiments of the disclosure.

FIG. 8 shows a top view of the structure with a lateral (along a plane of a material layer) offset is present, radially, between the mesa and a given trench.

FIG. 9 shows a schematic cross-section of VCSEL epitaxial layers formed on a substrate.

FIG. 10 is a schematic cross section showing a first processing step to fabricate a VCSEL, according to some embodiments of the disclosure.

FIG. 11A is a schematic cross section showing a second processing step to fabricate a VCSEL, according to some embodiments of the disclosure.

FIG. 11B is a schematic cross section showing a third processing step to fabricate a VCSEL, according to some embodiments of the disclosure.

FIG. 12A is a top view of the structure shown in FIG. 11A.

FIG. 12B is a top view of the structure shown in FIG. 11B.

FIG. 13 is a schematic cross section showing a fourth processing step to fabricate a VCSEL, according to some embodiments of the disclosure.

FIG. 14 is a top view of the structure shown in FIG. 13.

FIG. 15 is a schematic cross section showing a fifth processing step to fabricate a VCSEL, according to some embodiments of the disclosure.

FIG. 16 is a top view of the structure shown in FIG. 15.

FIG. 17 is a schematic cross section showing a sixth processing step to fabricate a VCSEL, according to some embodiments of the disclosure.

FIG. 18 is a top view of the structure shown in FIG. 17.

FIG. 19 is a schematic cross section showing a sixth processing step to fabricate a top-emitting VCSEL, according to some embodiments of the disclosure.

FIG. 20 is a top view of the structure shown in FIG. 19.

FIG. 21 is a schematic cross-section showing a top-emitting VCSEL, according to some embodiments of the disclosure.

FIG. 22 is a top view of the structure shown in FIG. 21.

FIG. 23 shows a top view of an array of top-emitting VCSEL devices, according to some embodiments of the disclosure.

FIG. 24 shows a top view of an array of top-emitting VCSEL devices, according to some embodiments of the disclosure.

### DETAILED DESCRIPTION

The following detailed description refers to the accompanying drawings that show, by way of illustration, specific details and embodiments in which the disclosure may be practiced. These embodiments are described in detail sufficient to enable those skilled in the art to practice the present disclosure. Other embodiments may be utilized, and structural, logical, and electrical changes may be made without departing from the scope of the disclosure. Various embodiments discussed below are not necessarily mutually exclusive, and sometimes can be appropriately combined. The following detailed description is, therefore, not to be taken in a limiting sense, and the scope of the embodiments of the present disclosure is defined only by the appended claims, along with the full scope of equivalents to which such claims are entitled.

Embodiments of the disclosure address at least two problems persisting in the art related to VCSEL devices employing intracavity electrical contacts: a problem caused by high electrical resistance of such devices existing along a plane of a material layer (e.g., a lateral resistance) and a problem cause by large material extent subject to oxidation during the manufacturing of such devices (large oxidation lengths).

The first problem manifests in and is caused by high electrical-resistance of a path that is formed by and/or available for free-carriers during the operation of such a device due to the conventional structure of the intracavity-contact containing VCSEL: the high electrical-resistance path leads to at least thermal build-up and heat and associated operational energy losses. According to embodiments of the disclosure, this problem is solved by disposing the intracavity contacts closer to an aperture of the VCSEL device than any conventionally-used structure can afford or implement, which is achieved with the use of judiciously dimensioned trenches or grooves formed in a constituent VCSEL material during the deposition thereof to substantially reduce or avoid processing challenges of related art, as discussed below.

Alternatively, or in addition, the second problem of long material oxidation length(s) and processing times, which is caused by lateral offset(s) between the mesa etch and the trench etch performed during the fabrication of the target VCSEL devices, as viewed in a plane of a material layer of the structure, is solved by judicious placement and dimensioning of the trenches such that the trenches are spatially interleaved with the contacts, wherein the interleaving permits disposing disposition of the trenches in close proximity of the VCSEL mesa.

The solution of either of these problems, as will be readily understood by a skilled artisan, results in geometrically-smaller VCSELs, and therefore higher spatial density arrays of such VCSELs, without the need to increase or improve the fabrication process control and/or reliability.

As a result of implementing embodiments of the disclosure, the carrier injection into the active region for carrier recombination is maintained at a level higher than that in devices of related art while at the same time, the heating of the material and its detrimental effects on semiconductor material gain is reduced, thereby increasing the overall efficiency of operation of the VCSEL device.

A person of ordinary skill in the art would understand that the numerical ranges and parameters used in the description are approximations, these numerical values in the specific examples are reported as precisely as possible. Any numerical value, however, inherently contains certain errors necessarily resulting from the standard variation found in their respective testing measurements.

In particular, any numerical range recited herein is intended to include all sub-ranges encompassed therein and are inclusive of the range limits. For example, a range of “1 to 10” is intended to include all sub-ranges between (and including) the recited minimum value of about 1 and the recited maximum value of about 10, that is, having a minimum value equal to or greater than about 1 and a maximum value of equal to or less than about 10.

Also, in this application, the use of “or” means “and/or” unless specifically stated otherwise, even though “and/or” may be explicitly used in certain instances.

The term “lattice-matched,” or similar terms, refers to semiconductor layers for which the in-plane lattice constants of the materials forming the adjoining layers materials (considered in their fully-relaxed states) differ by less than 0.6% when the layers are present in thicknesses greater than 100 nm. Further, in devices such as VCSELs with multiple layers forming individual regions (such as mirrors) that are substantially lattice-matched to each other means all materials in the junctions, that are present in thicknesses greater than 100 nm and considered in their fully-relaxed stated, have in-plane lattice constants that differ by less than 0.6%.

Alternatively, the term substantially lattice-matched or “pseudomorphically strained” may refer to the presence of strain within a layer (which may also be thinner than 100 nm), as would be understood from context of the discussion. As such, base material layers, of a given layered structure, can have strain from 0.1% to 6%, from 0.1% to 5%, from 0.1% to 4%, from 0.1 to 3%, from 0.1% to 2%, or from 0.1% to 1%; or can have strain less than 6%, less than 5%, less than 4%, less than 3%, less than 2%, or less than 1%. Layers made of different materials with a lattice parameter difference, such as pseudomorphically strained layers, can be grown on top of other lattice matched or strained layers without generating misfit dislocations. The term “strain” generally refers to compressive strain and/or to tensile strain.

The term “intracavity contact(s),” used in reference to a VCSEL structure, such as that from examples described below, is understood to mean, refer to, and is defined by an electrical contact layer disposed within (not outside) the layered VCSEL structure device, regardless of the exact location of such a contact. To be considered an intracavity contact, the electrical contact has to be disposed between the two outermost layers of the layered VCSEL structure. For example, an intracavity (electrical) contact may be formed inside a VCSEL reflector structured as a Distributed Bragg Reflector (DBR) (for instance, between two of the multiple DBR layers), or between the reflectors that bound the VCSEL laser cavity (that is, among the intracavity layers of the VCSEL structure). Phrased differently, an intracavity (electrical) contact layer is one that does not constitute the very top or the very bottom layer of the device.

### Exemplary Single Intracavity Electrical Contact (Electrically-Conducting) Layer

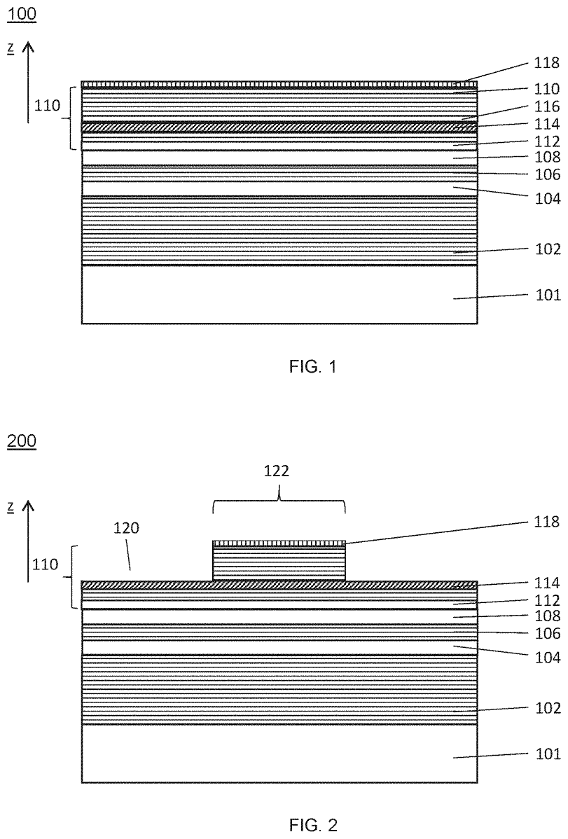

FIG. 1 shows a schematic cross-section of a semiconductor epitaxial layer structure 100 (e.g., a semiconductor epitaxial structure preform) that may be used to form a VCSEL with a single top-side intracavity contact, according to embodiments of the disclosure. Considering the structure 100 along the z-axis (that is transverse to the layers of the structure 100, as shown), the structure 100 includes a substrate 101, a first reflector layered structure (or first reflector, for short) 102 overlying or carried by the substrate 101; a first spacer layer 104 overlying the first reflector; an active region 106 overlying the first spacer layer 104; a second spacer layer 108 overlying the active region 106; an oxidizable layer 112 carried by the second spacer layer 108; an upper contact layer 114 overlying the oxidizable layer 112; an etch-stop or etch-control layer 116 overlying the upper contact layer 114; and a second (upper) reflector 110 on top of the second spacer layer 108.

As shown, the spacer layer 104, active region 106, and spacer layer 108 are included in the laser cavity that is limited by the reflectors 102 and 110. The laser cavity defines an associated resonance wavelength of operation. The thickness of the cavity is chosen to be an integer multiple of λ₀/2n, where λ₀ is the resonance wavelength in operation of the final device, and n is the refractive index of the material at the resonance wavelength. On the other hand, the oxidizable layer 112, upper contact layer 114, and etch control layer 116 are shown as layers within the second reflector 110 (in which case these layers are not considered to be layers of the laser cavity). Embodiments of the disclosure include these layers 112, 114, and 116 as layers within the cavity (that is, in the material region, the z-axis being limited by the reflectors 102 and 110; not shown in FIG. 1). Additionally, an optional protective layer 118 may overlie the second reflector 110.

The substrate 101 is preferably made from a semiconductor material such as gallium arsenide (GaAs), or indium phosphide (InP), but other semiconductor substrates such as gallium antimonide (GaSb), germanium (Ge), an epitaxially-grown material (such as a ternary or quaternary semiconductor), or a buffered or composite substrate can also be used in the alternative. The lattice constant of the substrate 101 material is judiciously chosen to minimize defects in materials subsequently grown thereon. The first reflector (or mirror) 102 is typically a semiconductor DBR with a lattice substantially matched to that of the substrate 101. As known in the art, a DBR is a periodic structure formed from alternating materials with different refractive indices that can be used to achieve high reflection within a range of frequencies or wavelengths. The thicknesses of the layers are chosen to be an integer multiple of the quarter wavelength, based on a desired design wavelength λ₀. That is, the thickness of a layer is chosen to be an odd integer multiple of λ₀/4n, where n is the refractive index of the material at wavelength λ₀. A DBR of the embodiment 100 can be structured to include, for example, semiconductor materials of Groups III and V of the periodic table such as, for example, AlAs, AlGaAs, GaAs, InAs, GaInAs, AlInAs, InGaP, AlInGaP, InGaP, InGaAsP, GaP, InP, AlP, AlInP, and AlInGaAs. When formed on a GaAs substrate, the DBR is formed using two different compositions for AlGaAs. Alternatively, or in addition, the mirror 102 can also be doped with an n-type dopant or a p-type dopant to facilitate current conduction through the structure of the overall device. The spacer layer 104, such as that made of AlGaAs or AlGaInP, may be formed overlying the first mirror 102.

In one implementation, the active region 106 is formed overlying the spacer layer 104 and includes a material configured to emit a substantial amount of light at a desired wavelength during the operation of the device 100. It will be understood that active region 106 can be structured to include at least one of various light emitting structures, such as quantum dots, quantum wells, or the like, in order to substantially improve a light emitting efficiency of the VCSEL fabricated from the structure 100. In an implementation in which a GaAs substrate is used, the active region 106 can include a material configured to emit light between wavelengths of about 0.62 μm and 1.6 μm. Notably, in reference to FIG. 1, while generally the active region 106 can include more than one material layer, in one embodiment, this region is considered to include a single layer, for simplicity and ease of discussion. For example, active region 106 can include GaAs/AlGaAs or InGaAs/GaAs or AlGaInP/InGaP or GaInNAsSb/GaAsN multiple quantum wells (MQWs). The spacer layer 108 that overlies the active region 106 may be formed from AlGaAs or AlGaInP.

The second reflector or mirror 110, carried by the spacer layer 108, is typically a DBR and is similar in design to the first reflector 102. In one specific embodiment illustrated in FIG. 1, the second reflector 110 is configured to include the oxidizable layer 112, an upper contact layer 114, and an etch-stop or etch-control layer 116. In other related embodiments, however, the oxidizable layer 112, upper contact layer 114, and an etch-stop or etch-control layer 116 may be configured to be layers in and/or of the laser cavity (which cavity in this case may be referred to as an extended cavity).

In a specific embodiment, when the structure 100 is formed on a GaAs substrate 101, the DBR of the second reflector 110 preferably includes two different compositions for AlGaAs. In such embodiment of an intracavity contact-containing VCSEL, the layers of the second reflector 110 is undoped, with the exception of the upper electrical-contact layer 114 (which may include GaAs). The upper contact layer 114 may be doped with a p-type dopant or an n-type dopant. This choice is made to ensure that the doping type is opposite to the doping type of the first reflector 102, in order to form a p-n junction and to facilitate current conduction through the device structure, once formed. While the upper contact layer 114 can generally include more than one material layer, this contact layer 114 is illustrated in FIG. 1 as including only one, single layer for simplicity and ease of discussion. The upper electrical-contact (or, simply, contact) layer 114 is formed to allow an electrical connection to be made between an auxiliary external element and the layer 114, through a subsequent metal deposition step. The upper contact layer 114 also provides the structure 100 with electrical conductivity in the vertical and lateral directions (that is, along the local z-axis and along a direction transverse to the local z-axis) to ensure current/electrical carrier spreading and injection into the active region 106. In an embodiment in which the upper contact layer is implemented as a structural layer in a reflector or mirror, the thickness of the upper contact layer 114 is chosen to be an odd integer multiple of an equivalent DBR layer thickness λ₀/4n (such that it also functions as a layer of the DBR itself). In some embodiments, when implemented as a layer between the reflectors 102 and 110 (that is, as part of contents of the extended laser cavity), the thickness of upper contact layer 114 is chosen to be an even integer multiple of λ₀/4n (such that the extended cavity length remains an integer multiple of λ₀/2n). Some examples of intracavity contact layers, including periodically-doped contact layers are described, for example, by: (1) Coldren in “Low-Power VCSEL-Based Smart Pixels with Simplified Optics,” ECE Technical Report #00-06; (2) MacDougal et al., “Low Resistance Intracavity-Contacted Oxide-Aperture VCSELs,” IEEE Photon. Technol. Lett. 10(1), pp. 9-11 (1998); and (3) U.S. Pat. No. 5,245,622, the contents of each of which are incorporated herein by reference.

The etch control layer 116 is disposed adjacent to and overlying the contact layer 114. While the etch control layer 116 can include more than one material layer, in FIG. 1 it is illustrated as including a single layer for simplicity and ease of discussion. In a specific embodiment of the preform 100, in which the layer 116 is implemented as a structural layer in or of a reflector (e.g., mirror) of the device 100, the thickness of layer 116 is chosen to be an odd integer multiple of an equivalent DBR layer thickness (such that it also functions as a layer of the DBR itself). On the other hand, in some embodiments, when implemented as a layer as part of the extended laser cavity, the thickness of the etch control layer 116 is chosen to be an even integer multiple of λ₀/4n (such that the extended cavity length remains an integer multiple of λ₀/2n). The availability and presence of the etch control layer 116 facilitates contacting the upper contact layer 114 during processing of the epitaxial structure 100. The etch control layer 116 may include a material that has a high etch selectivity (as compared with that of the adjacent layers within the structure 100, in particular, the underlying contact layer 114). In some examples, the etch control layer 116 may include a phosphide layer such as GaInP, AlInP, and AlGaInP, which has a very high etch selectivity with respect to GaAs, AlAs, and AlGaAs. Such choice of material enables one to etch down uniformly to the etch control layer 116 at a first etch step, followed by a second etch step of the etch control phosphide layer 116 to the top surface of the upper contact layer 114.

In some embodiments, the etch control layer 116 may include a thick AlₓGa₁₋ₓAs layer (with a thickness such as 5×λ₀/4n, 7×λ₀/4n, 9×λ₀/4n, etc., for example, when the layer 116 is implemented as part of the laser reflector; and with a thickness of 4×λ₀/4n, 6×λ₀/4n, or 8×λ₀/4n, etc. when the layer is implemented as part of the extended laser cavity, where λ₀ is the design wavelength and n is the refractive index of the etch control material), and where 0.97>x>0.5, or where 0.9≤x≤0.5, whereas the upper contacting layer 114 includes GaAs. According to embodiments of the disclosure, when the thickness value of the layer 116 is chosen to be large, a first etch step in an etch process can be used to end reliably in the etch control layer 116 (and regardless of whether a timed process of optical monitoring is implemented) with sufficient uniformity to allow a second selective etch step in the etch process (such as a hydrofluoric acid etch, which removes high Al-content material preferentially to low (or no) Al-content material) to remove the remainder of the etch control layer 116 and terminate at the surface of the upper contact layer 114.

In order to produce an efficiently operating VCSEL, the lateral current confinement and/or the lateral confinement of the optical field (providing waveguiding) is required, thus it is necessary to form a confinement region within a VCSEL structure. Confinement regions may be formed using oxidation, ion implantation, mesa etching, and combinations thereof. For the specific oxide-confined VCSEL structure shown in FIG. 1, the second reflector 110 also includes the oxidizable layer 112. The oxidizable layer 112 can include more than one material layer, but is illustrated as a single layer for simplicity and ease of discussion. The thickness of the layer 112 is chosen to be an odd integer multiple of an equivalent DBR layer thickness λ₀/4n (such that it also functions as a layer of the DBR itself). As was already alluded to above, in some embodiments, the oxidizable layer 112 may be implemented as part of the extended laser cavity (e.g., in the region between the reflectors 102 and 110) and may be devised with a thickness chosen to be an even integer multiple of λ₀/4n (such that the extended cavity length remains an integer multiple of λ₀/2n). For the purposes of this disclosure, the oxidizable layer 112 includes a material that can be oxidized when exposed to a steam environment, as is known in the art, thereby allowing a confining region to be formed that has material properties different from those of the adjacent regions, in order to provide waveguiding and/or to define a region for current injection within a VCSEL structure formed using epitaxial structure 100. For example, when formed on a GaAs substrate, oxidizable layer 112 can include AlₓGa₁₋ₓAs where x≥0.9 and/or x≥0.97.

The optional protective layer 118 may be additionally used to protect the top surface of the final VCSEL structure during the processing sequence to form the VCSEL. When present, the optional protective layer 118 may include a material that can be selectively removed from the epitaxial structure during processing. For example, when the structure 100 includes the formed on a GaAs substrate, the layer 118 may include InGaP lattice-matched to GaAs, or a sacrificial GaAs/AlGaAs layer deposited epitaxially during growth of the structure 100. In some embodiments, the protective layer 118 may include a dielectric layer (such as silicon nitride, silicon oxide, or the like) deposited by any of evaporation, sputtering, chemical vapor deposition (CVD), atomic layer deposition (ALD), or spin coating. The optional protective layer 118 may be removed at a later processing stage, or it may remain as a layer within a final device.

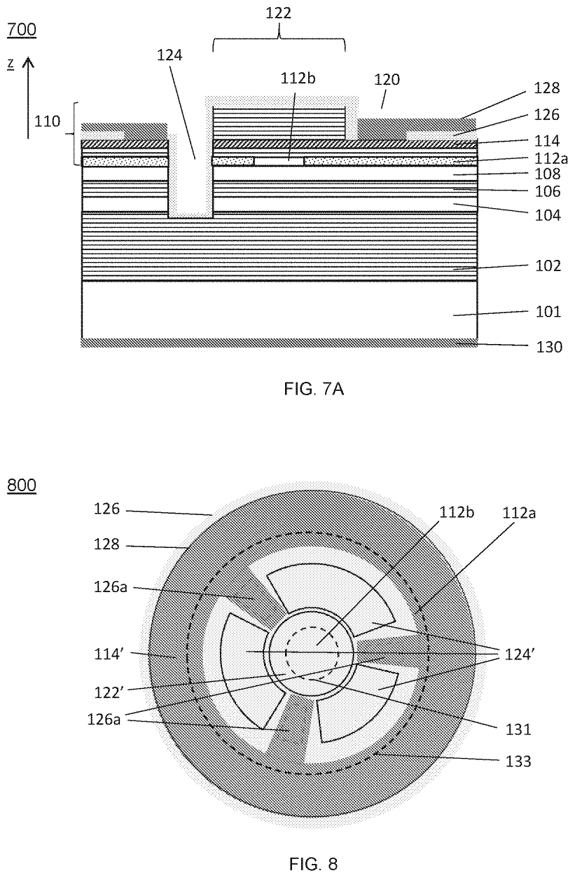

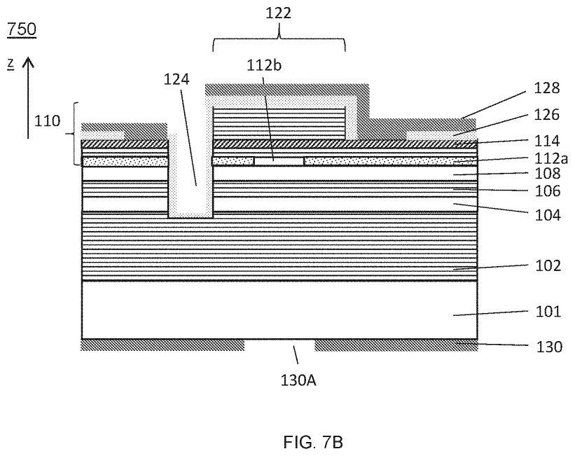

FIGS. 2, 3A, 3B, 4A, 4B, 5A, 6, 7A, 7B, and 8 illustrate particular sequence(s) of exemplary (non-limiting) steps of processing the preform 100 to form a VCSEL device structured according to embodiments 700 and 750 of FIGS. 7A, 7B. In related implementations, other/additional processing steps may also exist and/or the process steps may be performed in a different order, depending on a specific process flow.

A first step of the formation of a VCSEL device according to embodiments of the disclosure is schematically illustrated in FIG. 2. Here, the top surface of the epitaxial structure 100 is lithographically patterned and etched, 120, through the upper layers of the second mirror 110 and through the etch control layer 116 carried by the upper contact layer 114, to expose the surface of the upper contact layer 114 in the chosen portions of the structure 100. In doing so, a mesa 122 is formed in the second mirror 110. In some embodiments, the mesa 122 has a diameter between about 10 μm and 40 μm. The etch process 120 may be a wet chemical etch or it may be a dry etch (such as, for example, an inductance-coupled plasma (ICP) etch employing, for example, a mixture of BCl₃ and Cl₂ gasses), or it may be a combination of different etching techniques. The etch process 120 may include a single etch step (during which a single etch chemistry is used) or may have more than one step (and, accordingly, may use more than one etch chemical composition). A comprehensive list of wet etchants, etch rates, and selectivity relationships is provided, for example, by Clawson, in Materials Science and Engineering, 31 (2001) 1-438, Elsevier Science B.V. In some embodiments, the sidewall angle is smaller than 90° but greater than 80°, in which case the mesa 122 has a diameter at the base substantially equal to its diameter at the top of the structure, or within about 1 μm or 2 μm of the value of the diameter at the top.

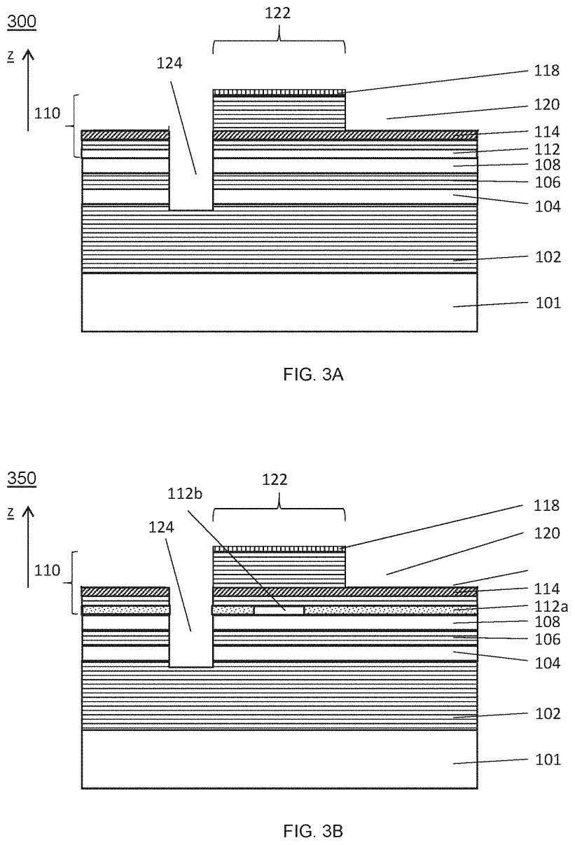

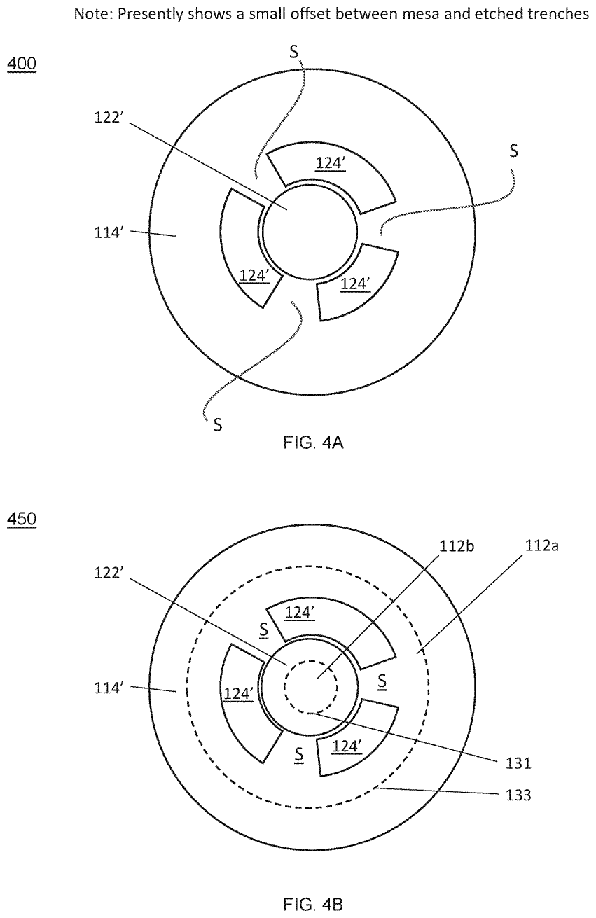

A person of ordinary skill in the art will readily appreciate that, in the following description presented in reference to FIGS. 3A, 3B, 4A, 4B, two similar layered structures are disclosed that may differ from one another only with respect to the presence (or absence) of a lateral offset (along a radius drawn in a plane of a material layer from the longitudinal axis of given structure) between a bottom portion of a mesa of the structure and a trench formed in such structure.

FIG. 3A illustrates the second step in the formation of the VCSEL device, according to embodiments of the disclosure. Here, patterned etched trenches 124 are formed using an etch process that goes past and through the oxidizable layer 112 and exposes the oxidizable layer 112, as shown. Typically, this etch process is a dry etch (such as an ICP etch) configured to define a sidewall angle (with respect to the surface of the device) of less than 90°, but greater than 80°, which ensures a well-defined surface for the subsequent oxidation step. The etching at the second step of the formation of the VCSEL device may be geometrically aligned with the preceding etch step 120 of FIG. 2 (that defined the mesa 122), or such etching can be slightly displaced radially (transversely with respect to the z-axis) outward by about 1 μm or 2 μm from the edge of the base of mesa 122 formed at the first processing step of FIG. 1, in order to minimize the oxidation time (and oxidation length) required to define a confining cavity aperture within the device.

FIG. 4A shows a top view of the structure (as seen in the −z direction) that is substantially similar to the structure formed at the processing step of FIG. 3A. The difference between the structures of FIG. 3A and 4A is that there is substantially no radial offset between the inner wall of a given trench 124 and the outer wall of the mesa 122 in FIG. 3A. A non-zero offset is shown in a related embodiment of FIG. 4A, and may account for mesa 122 having a sidewall angle between 90° and 80°, such that the base dimension of the mesa 122 is slightly larger than the top dimension of mesa 122, as previously described. As shown in the figure, 122′ indicates the top of the mesa structure 122, a surface 114′ is the surface of the upper contact layer 114, and surfaces 124′ are the bottom surfaces of (multiple) trenches 124 produced at the second etching step of FIG. 3A. Trenches 124 may generally be different in number (not three as shown, but two, four, or any other number greater than three). In some embodiments, the trenches may be formed with radially-measured widths between about 5 μm and 20 μm, or between 6 μm and 10 μm (depending on the particular embodiment) with a minimum separation between the neighboring trenches 124 (at a given radial distance from the z-axis passing through the center of the mesa 122) of about 5 μm to define “spoke” regions or isles (schematically illustrated as “S” in FIG. 4A) of material that have not been etched between the trenches and that contain material of the upper contact layer and to facilitate the deposition of metal between the trenches at a later processing step. While generally the trenches 124 may be of different shapes, in some embodiments, these trenches are dimensioned to have spatially-curved walls that are substantially tangentially-parallel to an outer wall of the mesa 122.

Next, an oxidation step (such as wet thermal oxidation, for example) as known in the art is performed as the third processing step. As shown in FIG. 3B, the oxidizable layer 112 is selectively oxidized in the geometrical region 112a while leaving an oxide-defined aperture 112b within the boundaries of the mesa 122. The oxidized portion 112a of the layer is not electrically conducting and so the aperture 112b is defined through which current can flow in a finished device. FIG. 4B shows, in top view, a structure substantially similar to that of FIG. 3B. The difference between the structures of FIG. 3B and 4B is that there is substantially no radial offset between the inner wall of a given trench 124 and the outer wall of the mesa 122 in FIG. 3B. A non-zero offset is shown in a related embodiment of FIG. 4B, which may account for mesa 122 having a sidewall angle between 90° and 80°, such that the base dimension of the mesa 122 is slightly larger than the top dimension of mesa 122, as previously described. The oxidation front from the etched trenches 124 extends under the mesa 122 to produce non-oxidized confinement or aperture region 112b (indicated by the inner dashed circle 131). The oxidized region also extends under the surface 114′ of the upper contact layer 114, including the regions between the etched trenches 124, thereby providing a continuous electrically-insulating region 112b to outward oxide front 133. While the oxidized (substantially non-electrically-conducting) portion 112a of the now-modified oxidizable layer is shown as an annular region, it is appreciated that generally outer and inner perimeters of the portion 112a are defined by closed curves and may have different ring-like shapes, each surrounding or circumscribing the longitudinal axis of the structure. In some embodiments, the structure 450 is substantially centered on such longitudinal axis. The length of oxidation (oxidation length) produced at this processing step is at least about 3 μm, in order to allow the oxidation to proceed under the spoke structures to provide for electrical isolation and form an oxide-defined aperture 112b that may have a diameter between about 4 μm and 35 μm.

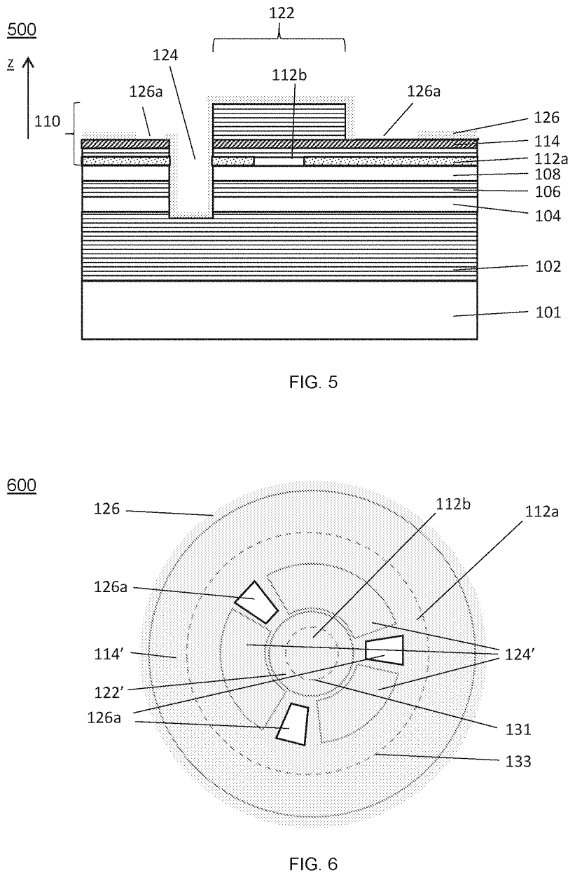

After the oxidation step, the optional protective layer 118 may be removed in some embodiments with the use of a selective etch or a timed etch process. Then, as shown in FIGS. 5 and 6, a dielectric layer 126 is deposited or formed (with the use of any of evaporation, sputtering, chemical vapor deposition (CVD), atomic layer deposition (ALD), spin coating, or any other well-known technique) over a surface of the structure 350 that is exposed to the ambient, and then appropriately patterned to remove the dielectric material and to form openings or apertures 126a over the regions “S” of FIGS. 4A and 4B that are dimensioned to establish a metal connection to the upper contact layer 114. The maximum width of the openings 126a is limited by the widths of the regions S (as seen in the plane transverse to the z-axis) between the etched trenches and is at least 4 μm. The dielectric layer 126 may include any of: silicon nitride, silicon oxide, silicon oxynitride, aluminum oxide, titanium oxide, or a combination thereof.

To form a top-emitting VCSEL (such as that shown in embodiments 700 of FIG. 7A and 800 of FIG. 8), a top metal contact 128 and a bottom metal contact 130 may then be deposited with the use of two metallization steps. Metallization may be carried out with evaporation, sputtering, and other known processes. Standard p-type (or n-type) ohmic metallization may be used to form the upper (top) contact 128, while standard n-type (or p-type) ohmic metallization may be used to form the lower (bottom) contact 130 on the underside of the substrate 101, as is known in the art. In some embodiments, the bottom metal 130 contact may be formed as a result of blanket deposition of metal on the bottom surface of the substrate 101, without the need for and use of lithography. The top metal contact 128, however, is formed using lithography to define the metal contact area, which overlaps with the dielectric openings 126a such that the material of the metal contact 128 is deposited on the surface 114′ exposed by and within the openings 126a, to establish electrical connection to the upper contact layer 114 of the device. The spatial interleaving of the metal contact 128 with etched trenches 124, formed according to embodiments of the disclosure, allows the metal contact to be brought closer to the mesa 122 of the device, thereby reducing the lateral conduction distance between the contact 128 and the conductive aperture region 112b. Furthermore, as a result of the so-formed spatial interleaving, any spatial offset between the mesa etch 120 and the trench etch 124 is reduced to less than about 2 μm (as measured from the base of the mesa 122), and in some embodiments, completely eliminates the need to have an offset between the oxide trench etch and mesa etch that otherwise exists in prior-art devices. In other words, the distance between a sidewall of the mesa 122 and a sidewall of the trench 124 may be less than about 2 μm. Spatial interleaving of the contact metal with etched trenches also removes any requirement for any use of bridging materials across the etched trenches in such devices. The presence of such a lateral (radial) offset between the mesa etch and the trench etch in the devices of related art increases the oxidation length usually required to form an oxide-defined aperture of a given size. The offset in the prior art devices allows for an electrical connection to be made to a portion of the contact layer between the mesa and the trench etch, such electrical connection requires the width of this portion of the conductive layer to be at least 5 μm, or at least 8 μm, as well as the use of additional bridging materials across the etched trench, resulting in a more complex process flow to fabricate the device.

Notably, the chosen procedure also allows for closer spatial packing of VCSELs (specifically, for closer aperture spacings) in a VCSEL array, as will be described later. The top metal contact 128 extends from the openings 126a outwards, above the dielectric layer 126 towards a top metal bond pad (not shown). The dielectric layer 126 may have a tapered thickness and/or may overlie an etched mesa structure (not shown) adjacent to the VCSEL device, the tapered thickness and/or adjacent mesa structure are designed to allow conformal step coverage of top metal contact 128 and the top metal bond pad.

A specific example of the structure of FIG. 7A is presented below as Example 1.

For a bottom emitting version of the VCSEL device 750, shown in FIG. 7B, the top metal contact 128 may be formed in a fashion discussed in reference to FIG. 7A, except the contact 128 may be formed to cover other portions of the top surface (such as the top surface 122′ of the mesa 122) with the conformal step coverage. The bottom metal contact 130 is formed on the backside surface of the substrate 101 using lithography to define the metal contact area with an opening 130A that is overlying and substantially aligned with the oxide-defined aperture 112b, to allow for and effectuate emission of light through the bottom surface of the final device. The size of the opening 130A is preferably equal to or greater than the size of the aperture 112b.

### Exemplary Dual Intracavity Electrical Contact Layers

The following portion of the disclosure discusses a related embodiment of the disclosure that is not exclusive from the embodiment discussed above.

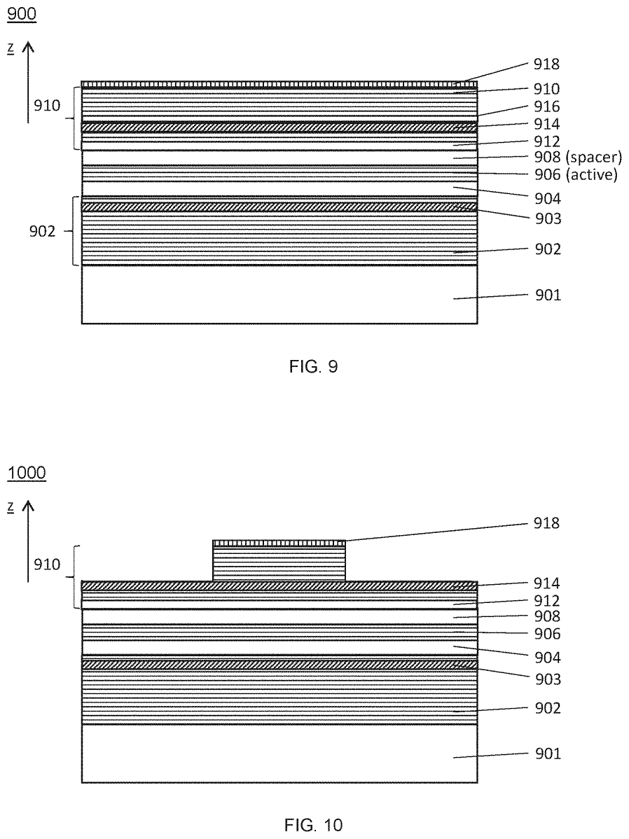

FIG. 9 illustrates a schematic cross-section of an epitaxial layer structure (a preform structure) 900 that is used to form an embodiment of a VCSEL device with dual intracavity contacts. The structure 900 is similar to the structure 100 of FIG. 1, except that in addition to the top electrical contact layer 914 (disposed between constituent layers of the DBR structure 910), it also includes a lower contact layer 903 underlying the active region. In this specific example, the lower intracavity electrical contact layer 903 is shown as part of the lower DBR reflector 902. In other words, in the example of FIG. 9, the first reflector structure 902 includes the lower contact layer 903 (that is absent in the first reflector structure 102 of the embodiment 100). Understandably, in a related implementation, such lower intracavity electrical contact layer may be disposed within the laser cavity (that is, in the stack of layers bound between the two DBRs 910 and 902) and below the active region of the device. The use of such second intracavity electrical contact obviates the need for an electrical contact to be made on the bottom side of the substrate 901 (which is a conventionally-accepted and used methodology). All other layers of the structures 100 and 900 are similar to one another or even identical, however.

Whereas the first (lower) reflector 102 of the embodiment of the epitaxial structure 100 was described as doped (either n-type or p-type), the corresponding first (lower) reflector 902 of the semiconductor epitaxial structure 900 is undoped, with the exception of the lower contact layer 903 (that may include GaAs). The lower contact layer 903 may be doped with either a p-type dopant or an n-type dopant (the doping type being opposite to the doping type of upper contact layer 914) in order to form a p-n junction and to facilitate current flow (electrical conduction) through the device structure, once formed from the epitaxial preform 900. While generally the lower contact layer 903 can include more than one material layer, this lower intracavity contact layer is illustrated in FIG. 9 as a specific non-limiting example of a single material layer, for simplicity and ease of discussion. The designs for the lower contact layer 903 and the upper contact layer 914 may be substantially identical, in some embodiments.

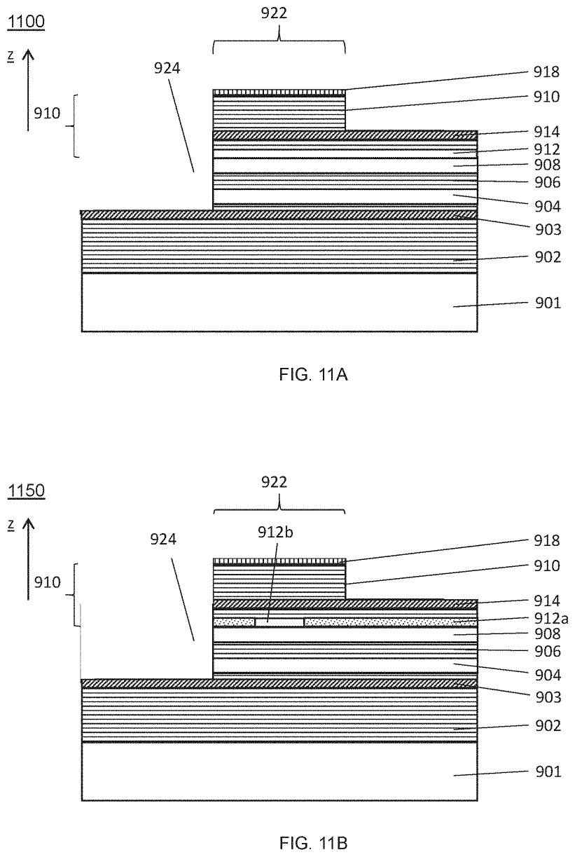

FIG. 10 illustrates the first step in the formation of a VCSEL device from the layered preform structure 900. The top surface of the epitaxial structure is lithographically patterned and an etch process 920 (similar to the etch process 120) is employed to etch through the upper layers of the second mirror 910 and through the etch control layer 916 overlying the upper contact layer 914, to expose the surface of the upper contact layer 914. In doing so, a mesa 922 is formed in the second mirror 910 (similar to the mesa 122 of the embodiment 100). Similarly, to the etch process 120, the etch process 920 may be a wet chemical etch or it may be a dry etch (such as an ICP etch), as previously described.

A person of ordinary skill in the art will readily appreciate that, in the following description presented in reference to FIGS. 11A, 11B, 12A, 12B, 13, 14 15, and 16, similar layered structures are simultaneously discussed that may differ from one another only with respect to the presence (or absence) of a lateral offset (along a radius drawn in a plane of a material layer from the longitudinal axis of given structure) between a bottom of the mesa of the structure and a trench formed in such structure.

FIG. 11A shows the second step in the formation of the VCSEL device. A patterned etched trench 924 is formed using an etch process that goes past, through, and exposes the oxidizable layer 912, as shown. Typically, this etch process is a dry etch such as an ICP etch, to provide a sidewall angle (with respect to the surface of the device) that is smaller than 90°, but greater than 80°, which ensures a well-defined surface for the subsequent oxidation step. The etch geometry may be aligned with the preceding etch step 920 that defines the mesa 922, or displaced radially outward by about 1 μm or 2 μm or so from the edge of the base of mesa 922, to minimize the oxidation time (and oxidation length) required to define a confining cavity aperture within the device. During the etch process 924, the upper contact layer 914, oxidizable layer 912, spacer layer 908, active layer 906, spacer layer 904, and any layers of the first reflector 902 (overlying lower contact layer 903 layer) are etched through to expose the surface of the lower contact layer 903. In some embodiments, a lower etch control layer (similar to the etch control layer 916 or 116; not shown) may be used above the lower contact layer 903 to ensure that the etch process 924 is stopped at the lower contact layer 903, thereby exposing the top surface of the lower contact layer 903.

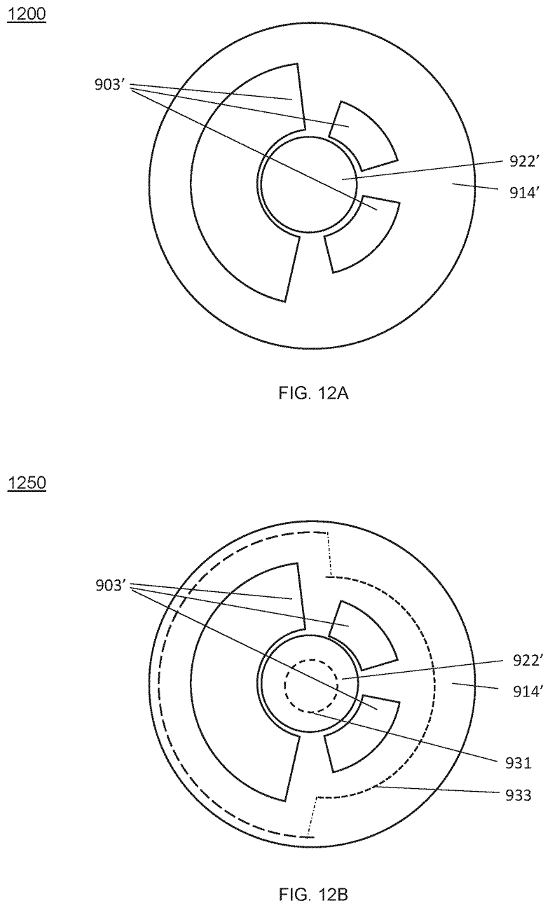

FIG. 12A shows the structure formed after the process of FIG. 11A, in a top view. The mesa structure 922 has a top surface 922′. The first etch step 920 produces a surface 914′ on the upper contact layer 914, and the second trench etch step produces trenches 924 with surfaces 903′ on the lower contact layer 903. Trenches 924 may have widths between about 5 μm and 20 μm, or between about 6 μm and 10 μm, in some embodiments. Additionally or alternatively, the trenches may be separated from one another by a minimum separation distance of about 5 μm to define a spoke between the trenches and to allow for metal deposition between the trenches at a later processing step.

Next, as illustrated in FIG. 11B, an oxidation step (such as wet thermal oxidation) is performed as known in the art to form the structure 1150. Here, the oxidizable layer 912 is oxidized in the geometrical region 912a while leaving an oxide-defined aperture 912b within the boundaries of the mesa 922. The oxidized portion of the layer is not electrically conducting and so defines an aperture 912b, through which current flows in a finished device. FIG. 12B shows the structure 1150 in a top view. The oxidation front from the etched trenches extends under the mesa to produce non-oxidized confinement or aperture region 912b (indicated by the inner dashed circle 931). The oxidized region also extends under surface 914′ of contact layer 914, including the regions between the etched trenches 924, providing a continuous electrically insulating region 912b to outward oxide front 933. The oxidation length is at least 3 μm, thereby allowing the oxidation to proceed under the spoke structures to form electrical isolation, as well as to provide an oxide-defined aperture 912b that may have a diameter between about 4 μm and 35 μm.

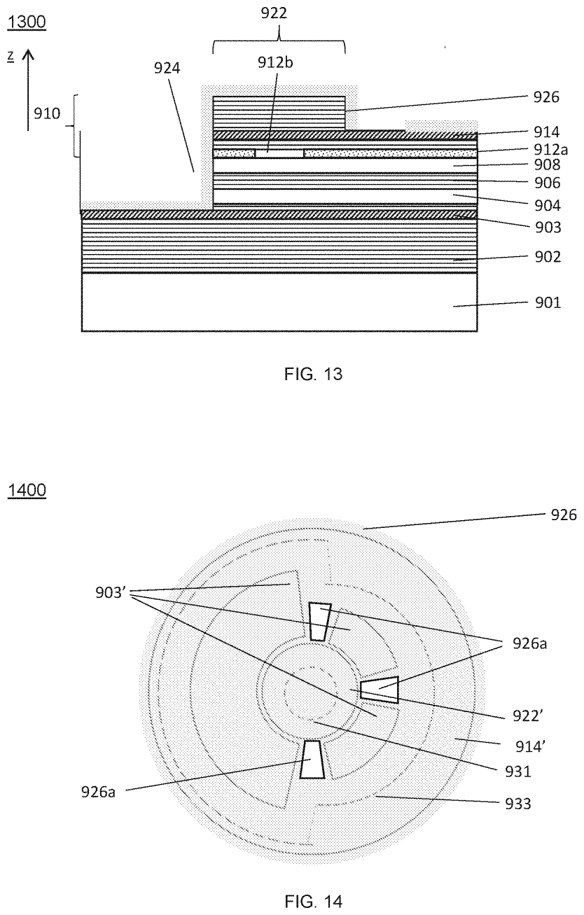

After the oxidation step, the optional protective layer 918 may be removed using a selective etch or a timed etch. Then, as shown in FIGS. 13 and 14, a dielectric layer 926 is deposited and patterned, leaving openings 926a for a metal connection to the upper contact layer 914. The dielectric layer 926 may include silicon nitride, silicon oxide, silicon oxynitride, aluminum oxide, titanium oxide, or a combination thereof. The dielectric layer 926 may be deposited with the use of well-known dielectric deposition processes such as evaporation, sputtering, chemical vapor deposition (CVD), atomic layer deposition (ALD), spin coating and the like. The dielectric layer 926 is lithographically patterned to remove the dielectric to form openings 926a. The maximum width of the openings is limited by the spoke width between the etched trenches 924 and is at least about 4 μm

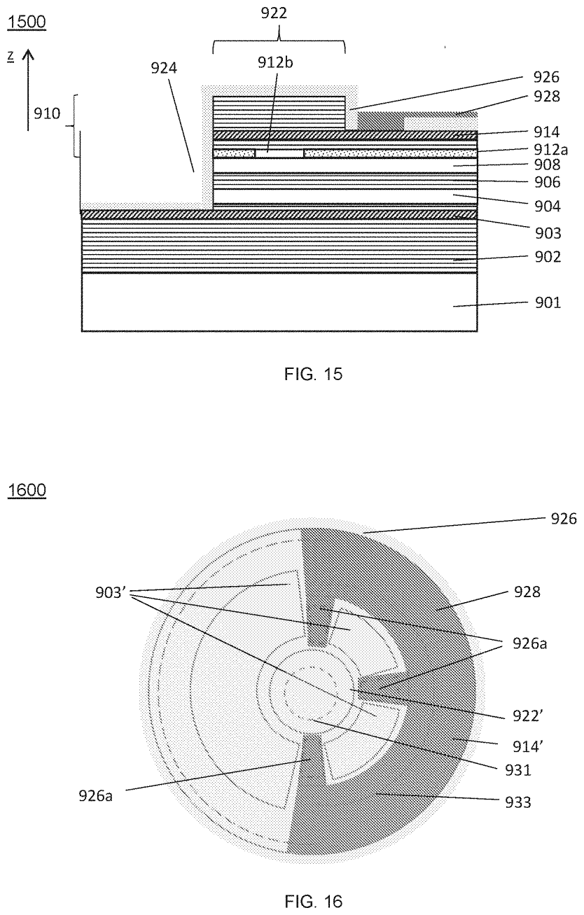

The top metal contact 928, shown in FIGS. 15 and 16, may then be deposited at a metallization step of the procedure. Metallization may be carried out using known processes such as evaporation or sputtering, for example. The top metal contact 928 is formed using lithography to define the metal contact area, which overlaps with dielectric openings 926a such that metal contact 928 is formed on the surface 914′ exposed by the openings 926a, thereby establishing electrical connection to the contact layer 914 of the device. The spatial interleaving of the metal contact 928 with the etched trenches 924 enables to bring (position) the metal contact closer to the mesa of the device, thereby causing and enabling the reduction of the lateral conduction distance between the contact 928 and the conductive aperture region 912b. Furthermore, such interleaving minimizes any spatial offset between the mesa etch 920 (measured at the base of the mesa 922) and the trench etch 924 to less than about 2 μm. Furthermore, in some embodiments, the interleaving eliminates the need to have an offset between the oxide trench etch and the mesa etch (which offset otherwise exists in the related-art devices). Interleaving contact metal with etched trenches according to embodiments of the disclosure also eliminates any requirement for bridging materials to be used across the etched trenches in such devices. Such a lateral offset (between the mesa etch and the trench etch, as viewed in a plane of a material layer of the structure) in prior art devices increases the oxidation length usually required to form an oxide-defined aperture of a given size. While in prior-art devices, such an offset also allows electrical connection to be made to a portion of the contact layer between the mesa and the trench etch, such electrical connection requires the width of this portion of the conductive layer to be at least 5 μm, as well as the use of additional bridging materials across the etched trench, resulting in a more complex process flow to fabricate the device. The proposed design approach also allows for denser spatial packing of VCSELs (that is, smaller spacings between the apertures) in a VCSEL array, as will be described later. The top metal contact 928 extends from the openings 926a outwards, above the dielectric layer 926 towards a top metal bond pad (not shown). The dielectric layer 926 may be tapered (have a monotonically-changing thickness) and/or may overlie an etched mesa structure (not shown) adjacent to the VCSEL device. In this case, the tapered thickness and/or adjacent mesa structure are configured to allow for a conformal step coverage of the top metal contact 928 and the top metal bond pad. Metallization procedure performed according to this embodiment facilitates the fabrication of either a top-emitting VCSEL or a bottom-emitting VCSEL, such that the direction of laser emission is determined by and through the reflector with the fewer number of mirror layer pairs and/or the lowest reflectivity. For a bottom-emitting VCSEL, the metal deposition with conformal step coverage can also be utilized in other regions of the top surface, such as the top surface of the mesa 922.

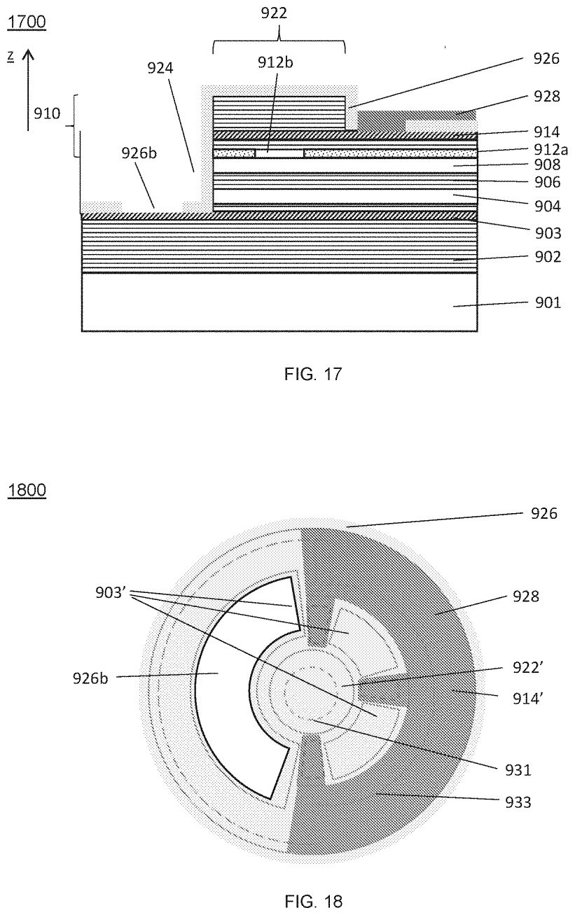

To produce a lower metal contact, the dielectric layer 926 is lithographically patterned with openings 926b′ spatially overlaying the surfaces 903′ of the lower contact layer 903, such that the surfaces 903′ (forming the bottom of the trenches 924) can be directly viewed through the openings 926b′ as shown in FIGS. 17 and 18. It should be noted that an opening 926b′ is formed over at least one of the trenches 924, and not necessarily over every etched trench 924, because interleaving of the top metal contact 928 effectively isolates some trenches from being planarly metallized in a subsequent lower contact metallization step.

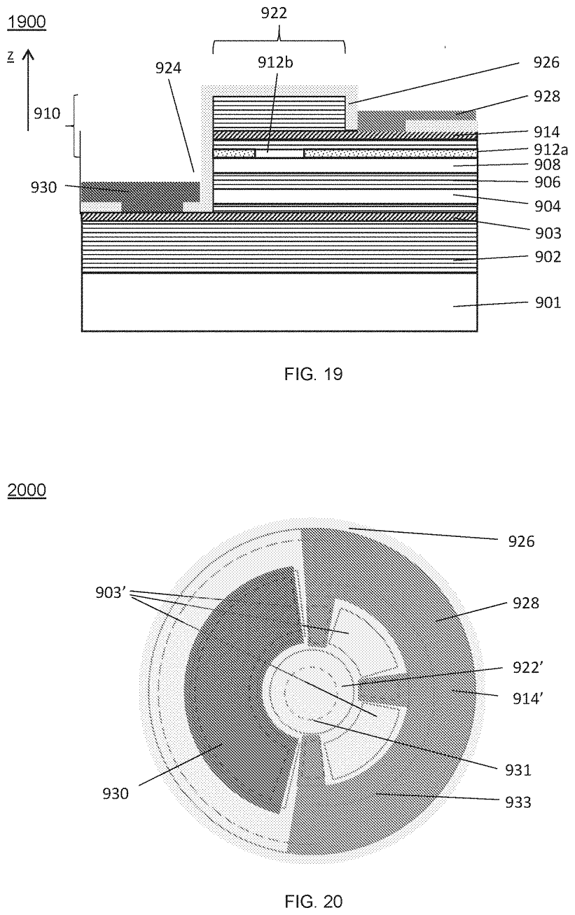

The lower metal contact 930 is then formed to be in contact with the top surface 903′ of the lower contact layer 903 via the dielectric openings 926b, as shown in FIGS. 19 & 20. The bottom metal contact 930 extends from the openings 926b outwards, above the dielectric layer 926 towards a bottom metal bond pad (not shown).

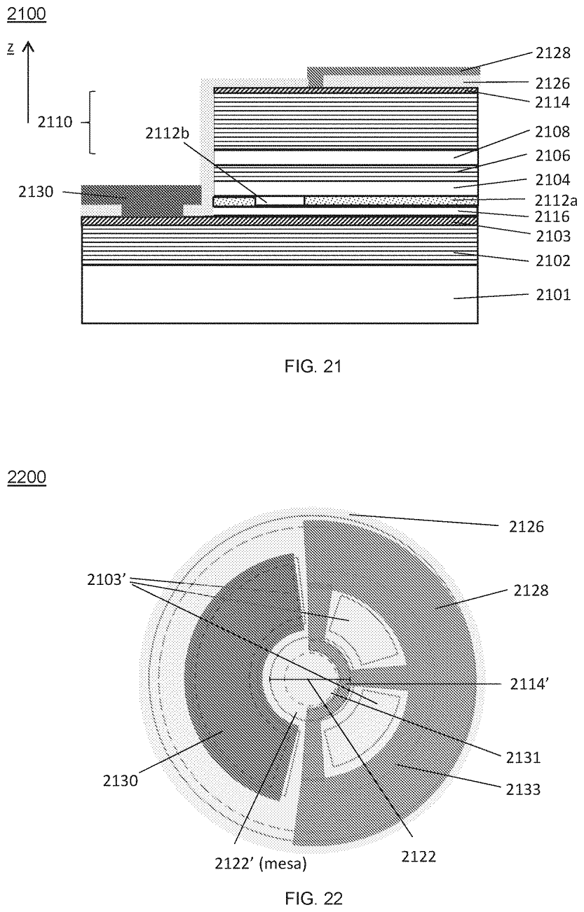

In some embodiments, a VCSEL device may have an intracavity contact underlying the active region. A cross-section of such embodiment 2100 of the VCSEL is shown in FIG. 21. The initial semiconductor epitaxial layered structure used for manufacture of VCSEL 2100 is similar to the epitaxial layer structures shown in FIG. 1 and/or in FIG. 9. In this example, however, the second (top) reflector 2110 is a doped DBR-mirror layer, while the lower DBR 2102 is undoped, with the exception of the lower intracavity contact layer (intracavity electrically-conducting layer) 2103. In this example, the lower intracavity contact layer 2103, the etch control layer 2116, and the oxidizable layer 2112 (part of which is oxidized to form region 2112a that defines an electrically-conducting aperture 2112b in the layer 2112) are all structurally included above the first (lower) distributed reflector 2102, as part of an extended laser cavity, but in some embodiments these layers can be structurally included in the first (lower) DBR 2102. The design and function of these layers has been described above (whether with respect to implementing these layers in a DBR and/or as part of an extended laser cavity).

FIG. 22 shows a top view 2200 of the device 2100. The lower metal contact 2130 is formed in direct physical and electrical contact with the lower intracavity contact layer 2103. The top metal contact 2128 is disposed on and in direct electrical contact with the top contact layer 2114 of the VCSEL, which top contact layer is the top-most semiconductor layer of the top DBR 2110. In this example, the VCSEL is configured as a top-emitting VCSEL structure, and the top metal contact 2128 is dimensioned to define an aperture to allow light (that is generated in a region of the aperture defined by the oxidation front 2131) to be emitted through such aperture.

A person of skill in the art will readily appreciate that a similar approach can be employed to form a bottom-emitting device. In this instance, the dielectric opening for the top contact can extend across the mesa 2122, thereby allowing an electrical contact to be made across the entire surface 2122′ of the mesa 2122. Light is then emitted through the substrate 2101.

It should be noted that substantially any of the above-discussed embodiments of VCSELs may include other (auxiliary) layers and regions, such as current spreading layers, additional oxidizable layers, passivation layers and ion-implanted regions, some of which may be optional layers. However, these layers and regions have not been shown in the corresponding drawings for the sake of clarity.

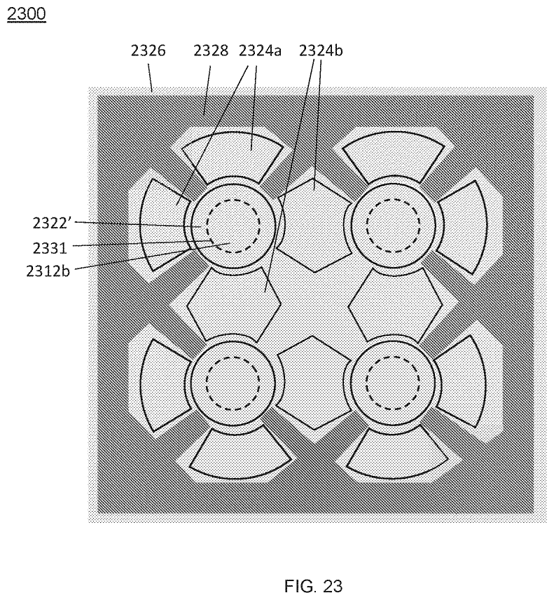

In embodiments including arrays of VCSEL devices, the oxidation features can be optionally shared (or overlapped) between adjacent devices in the array to provide compact arrays with closely-spaced VCSEL output apertures. However, in some array oxidation features are not shared between adjacent constituent devices of an array. A top view of an embodiment 2300 of a VCSEL array is shown in FIG. 23. The VCSEL array 2300 is a 2-by-2 array of constituent top-emitting VCSELs with a single, one (shared by the constituent VCSELs) intracavity contact overlying the active regions of the constituent VCSEL emitters. Etched trenches 2324a and 2324b are formed in a fashion similar to that described in reference to etched trenches 124 of the embodiment of FIG. 3A. In some embodiments, etched trenches are unique to a given VCSEL emitter in the array, the trenches are denoted 2324a. These trenches are fabricated at the periphery of the device array. However, where etched trenches are shared between adjacent constituent VCSELs, the etched trenches are denoted 2324b. As shown, for example, immediately adjacent constituent VCSEL devices in a given row or a given column of the array 2300 share a trench 2324b, while at the same time having two individual trenches 2324a. The oxidation front 2331 that extends from the etched trenches defines a VCSEL aperture 2312b, through which aperture the current flows and from which light is emitted during the operation of the array 2300. Each individual VCSEL emitter of the array is configured to have an interleaved arrangement of metal contacts with etched trenches, as previously described. The metal contact 2328 overlies the dielectric layer 2326, as shown. In one example of array 2300, mesas 2322 (having top surfaces 2322′) of each constituent VCSEL emitter each may have a diameter of about 10 μm. The etched trenches 2324 may have a width of about 5 μm, with a substantially zero lateral offset with respect to the corresponding mesas. Overlapping/shared trenches may have a width of about 10 μm, thereby providing an array of VCSEL with an aperture spacing of about 20 μm. The shared oxide trench width may be as low as the width of a single trench, thereby allowing a smaller aperture spacing of 15 μm for devices having a 10 μm mesa size.

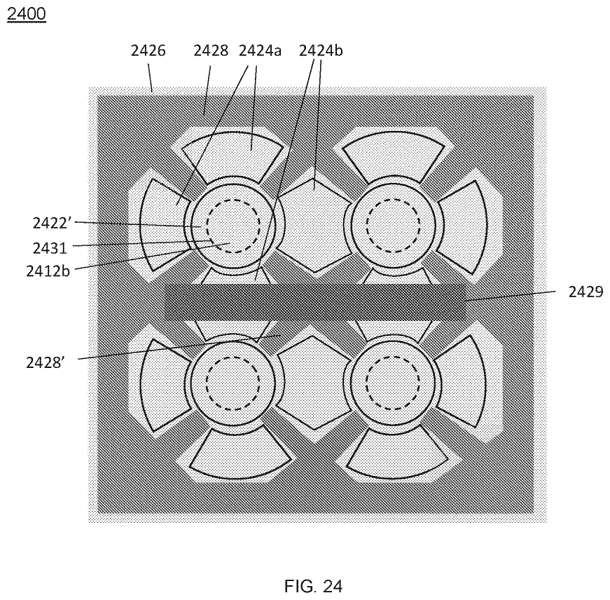

For a 1-by-n array (linear array) or a 2-by-n array (such as the array shown in FIG. 23), emitting VCSEL elements can be electrically connected together with a closed upon itself metal contact 2328 dimensioned around/along the periphery of the array. For an n-by-n array, where n is greater than 2, and where etched trenches are shared between or among the constituent VCSEL elements, portions of a top contact metal 2428′ may exist that are confined by inner portions of the array surrounded by the shared etched trenches 2424b, as shown in FIG. 24. Thus, to electrically connect portions 2428′, the metal contact 2428 may employ (or even require to employ) a bridging metal portion 2429. As a result of deposition of such a metal portion, a bridge may be formed over the trenches 2424b. Consequently, some of the shared etched trenches 2424b may also need to be filled during the deposition step for dielectric layer 2426, and bridging metal portion 2429 is formed in a subsequent additional metallization step. For arrays where trench etches for a device are not shared or do not overlap with one another, the trenches of the adjacent constituent VCSEL devices in an array of VCSELs may be separated by at least about 5 μm. Consequently, the metal contact 2428 may interleave all devices of the array, which may be connected together electrically, without the use of bridging materials such as patterned dielectric layers and additional metallization steps.

### Example 1—Single VCSEL Device with a Top Intracavity Contact Layer

In one non-limiting example, a top-emitting VCSEL is designed to operate at about 1300 nm (λ₀) and has a single top-intracavity contact, similar to the structures discussed in reference to FIGS. 7A & 8. The VCSEL is fabricated using a dilute nitride semiconductor material-based quantum well active region. Examples of dilute nitride materials include GaInNAs, GaInNAsSb, GaNAsSb, GaInNAsBi, GaInNAsSbBi, GaNAsBi, and GaNAsSbBi. Examples of semiconductor laser and VCSEL devices that employ dilute nitride are described in U.S. Pat. No. 6,798,809 and in U.S. Pat. No. 7,645,626, the disclosure of each of which is incorporated herein by reference. In this case, the quantum well active region is placed between two GaAs spacer layers with physical thicknesses λ₀/2n, where n is the refractive index of the spacer layer. The VCSEL has a lower n-doped Al_{0.9}Ga_{0.1}As/GaAs DBR with 36 mirror-layer pairs, which is doped with Silicon at doping levels between about 1×10¹⁷ cm⁻³ and 5×10¹⁸cm⁻³, and an upper undoped Al_{0.9}Ga_{0.1}As/GaAs DBR with 24 mirror-layer pairs. Each mirror-layer pair has a physical thickness of approximately 205 nm. Underlying the upper DBR is an AlGaAs etch control layer with a physical thickness λ₀/n, where n is the refractive index of the etch control layer. This etch control layer is implemented as part of (and inside) the extended laser cavity. The physical thickness of the etch control layer is approximately 0.43 μm. Underlying the etch control layer is a contacting and current-spreading layer with a spatially-periodic p-doping profile, as is known in the art (in one example, carbon doping is used), with the highest level of doping occurring at the locations of nulls or nodes of the standing-wave electric field formed in the cavity device, and with lower doping levels in the space between the nulls. The p-doping level accordingly varies, therefore, between about 2×10¹⁷ cm⁻³ and 8×10¹⁹ cm⁻³. The contacting and current-spreading layer has a physical thickness 2×λ₀/n (approximately 0.82 μm). The oxidizable layer has a physical thickness of λ₀/2n, where n is the refractive index of the material of this layer, and includes a 25 nm thick Al_{0.98}Ga_{0.02}As sub-layer placed at a null or node of the standing wave electric field and surrounded by AlₓGa₁₋ₓAs where x≤0.9.

Mesas are formed (with diameters between about 10 μm and 40 μm) by a timed ICP etch using Cl₂/BCl₃ chemistry, which etches through the top 24 mirror-layer pairs to a depth of at least 4.9 μm and up to about 5.3 μm, stopping at the AlGaAs etch control layer. The remainder of the AlGaAs etch control layer is then removed using a selective HF etch. A second patterned trench etch is then performed to etch through the contact layer, oxidizable layer, and cavity layers. This process is also an ICP etch that utilizes Cl₂/BCl₃ chemistry. The etched trenches are formed as curved grooves that are substantially concentric with the etched mesas, with an inner diameter of such grooves having a value that is either substantially equal to the diameter of the first mesa at the base of the first mesa, or that does not exceed such mesa diameter by more than The etched trenches have widths of about 10 and spacing of about 6 to allow metal interleaving in a subsequent metal deposition step. When a 10 μm diameter etched mesa is intended, its circumference at the base of the mesa is about 32 and two etched trenches with inner radial lengths of about 10 μm and a separation of about 6μm are formed. To produce a device with a 25 μm diameter mesa, the circumference is assessed at about 78 and five etched trenches with inner radial lengths of about 10 μm and separation between the neighboring trenches of about 6 μm may be formed. For a 40 μm diameter mesa, the circumference is about 125 and six etched trenches with inner radial lengths of about 15 μm and separations between the trenches of about 6 μm may be formed (or, alternatively, six etched trenches with inner radial lengths of about 11 μm and separations of about 10 μm may be formed; or five etched trenches with inner radial lengths of about 15 μm and separations of about 10 μm may be formed—these provide but examples of various possible structures). The etch depths for these trenches is at least 3 μm. However, any other suitable etch depth that penetrates through the upper contact layer, the oxidizable layer, and the cavity layers may also be aimed at.

Wet thermal oxidation is performed at a temperature of approximately 420° C., as is known in the art to define the device aperture. The optional protective cap can then then be removed, and a SiO₂ dielectric layer is deposited on the top surface of the multilayer structure. The physical thickness of the dielectric is approximately λ₀/2n, where n is the refractive index of such dielectric. A selective reactive ion etch (RIE) is performed to open up windows in the dielectric, with a width of about 5 μm to fit between the trenches, and a length approximately equal to the width of the trenches. Standard p-type ohmic metallization is then used to form the upper contact, while standard n-type ohmic metallization is used to form the lower contact on the underside of the substrate, as is known in the art.

To fabricate embodiments of semiconductor optoelectronic devices structured according to embodiments of the disclosure, a plurality of layers can be deposited on an appropriate substrate in a first-material-deposition step (in one implementation, this first deposition step can be performed in a first material-deposition chamber). The plurality of layers may include etch-stop layers; release layers (i.e., layers designed to release or let free the semiconductor layers from the substrate when a specific process sequence, such as chemical etching, is applied); contact layers such as lateral conduction layers; buffer layers; layers forming reflectors or mirror structures, and/or or other semiconductor layers to form a first stack of materials. For example, the sequence of layers deposited in a first deposition step can include buffer layer(s), then a lateral conduction or contact layer(s), and then layer(s) forming a reflector of the VCSEL structure. Next, the substrate with the first stack of materials thereon can be processed according to a second material-deposition step (which, in a specific case can be performed in a second-materials-deposition chamber to which the built-upon substrate can be appropriately transferred). Here, a laser cavity region and an active region are formed on top of the existing, already-deposited first stack of semiconductor layers: now the substrate carried a second stack of material layers. The substrate with the second stack of material layers thereon may then be exposed to a third deposition step, during which it is transferred to either the first-materials-deposition chamber or yet another, third-materials-deposition chamber for deposition of additional mirror layer(s) and contact layers. Notably, in some implementations tunnel junction portion(s) of the overall semiconductor structure may also be formed during at least one of the first, second, and third material deposition steps.

The movement or repositioning/relocation of the substrate with a stack of semiconductor layers thereon from one deposition chamber to another chamber is referred to as transfer. The transfer may be carried out in vacuum, at atmospheric pressure in air or another gaseous environment, or in an environment having mixed characteristics. The transfer may further be organized between materials deposition chambers in one location, which may or may not be interconnected in some way, or may involve transporting the substrate and semiconductor layers between different locations, which is known as transport. Transport may be done with the substrate and semiconductor layers sealed under vacuum, surrounded by nitrogen or another gas, or surrounded by air. Additional semiconductor, insulating or other layers may be used as surface protection during transfer or transport, and removed after transfer or transport before further deposition.

For example, a dilute nitride active region and cavity region can be deposited in a first-materials-deposition chamber, while the AlGaAs/GaAs DBRs and other structural layers can be deposited at a second deposition step in a second-materials-deposition chamber. To fabricate VCSEL devices discussed in this disclosure, some or all of the layers of a cavity region (including a dilute-nitride-based active region) can be deposited with the use of molecular beam epitaxy (MBE) in one deposition chamber, and the remaining layers of the laser can be deposited with the use of chemical vapor deposition (CVD) in another material-deposition chamber.

In some embodiments, a surfactant, such as Sb or Bi, may be used when depositing substantially any of the layers of the device. A small fraction of the surfactant may also incorporate within a layer.

A semiconductor device comprising a dilute nitride layer can be subjected to one or more thermal annealing treatments after growth. For example, a thermal annealing treatment includes the application of a temperature in a range from about 400° C. to about 1,000° C. for a duration between about 10 microseconds and about 10 hours. Thermal annealing may be performed in an atmosphere that includes air, nitrogen, arsenic, arsine, phosphorus, phosphine, hydrogen, forming gas, oxygen, helium, or any combination of the preceding materials.

The embodiments as recited in claims appended to this disclosure is intended to be assessed in light of the disclosure as a whole, including features disclosed in related art to which reference is made.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In some embodiments, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +/−20% of the value itself, preferably within the +/−10% range of the value itself, more preferably within the range of +/−5% of the value itself, and even more preferably within the range of +/−2% or less of the value itself. The term “substantially equivalent” may be used in the same fashion.

The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes.

Although specific embodiments have been illustrated and described herein, it will be appreciated by those of ordinary skill in the art that any arrangement that is devised to achieve the same purpose may be substituted for the specific embodiments shown. In a related embodiment, for example, a VCSEL structure is provided that has a longitudinal axis and that includes first and second reflectors; a gain medium between the first and second reflectors; and a peripheral material layer defining an output aperture therein (the output aperture dimensioned to have no more than two axes of symmetry of the output aperture; here, the peripheral material layer is a metallic layer configured as an electrical contact layer of the VCSEL structure, and the peripheral material layer is dimensioned to include a first peripheral portion and a second portion surrounded by the first peripheral portion). Such VCSEL structure may be configured to produce, in operation, a light output having a spatial distribution of intensity in one of the following forms: a) a ring-shaped distribution of intensity, and b) a dumb-bell-shaped distribution of intensity, as defined in a plane transverse to an axis of the light output, while an axis of the output aperture and an axis of the at least one internal aperture may be configured to not coincide with one another, and/or while a lateral extent of at least one of the peripheral material layer and the at least one confining material layer (in a first plane that is transverse to the longitudinal axis) may be chosen to be smaller than a lateral extent of the active region (in a second plane that is parallel to the first plane).

Overall, this application is intended to cover any adaptations or variations of embodiments of the disclosure. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description. The scope of the disclosure includes any other applications in which embodiment of the above structures and fabrication methods are used. The scope of the embodiments of the disclosure should be determined with reference to claims associated with these embodiments, along with the full scope of equivalents to which such claims are entitled.

1. A semiconductor epitaxial structure comprising:
a first reflector;
a second reflector comprising an oxidizable layer, an upper contact layer, and a mesa;
a plurality of layers located between the first reflector and the second reflector; and
a plurality of trenches formed in the plurality of layers,
wherein the plurality of trenches is located around the mesa, and
wherein each of the plurality of trenches is spatially separated from another trench by a region, the region including at least a portion of the upper contact layer.

2. The semiconductor epitaxial structure of claim 1, wherein the plurality of trenches are further formed in the oxidizable layer and the upper contact layer.

3. The semiconductor epitaxial structure of claim 1, wherein the oxidizable layer comprises an oxide-defined aperture and an oxidized portion, the oxidized portion surrounding the oxide-defined aperture.

4. The semiconductor epitaxial structure of claim 3, further comprising:
a bottom metal contact, the bottom metal contact having an opening, wherein the oxide-defined aperture is overlying and substantially aligned with the opening.

5. The semiconductor epitaxial structure of claim 1, wherein walls of the plurality of trenches form an annual shape.

6. The semiconductor epitaxial structure of claim 1, wherein a top diameter of the mesa is substantially equal to a base diameter of the mesa.

7. The semiconductor epitaxial structure of claim 1, further comprising:
a dielectric layer overlying the upper contact layer, the dielectric layer including a plurality of openings overlying the regions between the plurality of trenches; and
a top metal contact electrically connected to the upper contact layer at the plurality of openings.

8. The semiconductor epitaxial structure of claim 7, wherein the top metal contact is overlying the mesa.

9. The semiconductor epitaxial structure of claim 1, wherein a distance between a sidewall of the mesa and a sidewall of one of the plurality of trenches is less than 2 μm.

10. The semiconductor epitaxial structure of claim 1, wherein the plurality of trenches excludes a bridging material.

11. The semiconductor epitaxial structure of claim 1, wherein the semiconductor epitaxial structure is a vertical-cavity surface-emitting laser (VCSEL).

12. A semiconductor epitaxial structure comprising:
a first reflector comprising a lower contact layer;
a second reflector comprising an upper contact layer and a mesa;
a plurality of layers located between the first reflector and the second reflector; and
a plurality of trenches formed in all of the plurality of layers,
wherein the plurality of trenches is located around the mesa, and
wherein each of the plurality of trenches is spatially separated from another trench by a region, the region including at least a portion of the upper contact layer.

13. The semiconductor epitaxial structure of claim 12, further comprising:
a dielectric layer overlying the upper contact layer, the dielectric layer including a plurality of openings overlying portions of the lower contact layer; and
a lower metal contact electrically connected to the lower contact layer at the plurality of openings.

14. The semiconductor epitaxial structure of claim 13, wherein the dielectric layer overlies the mesa.

15. The semiconductor epitaxial structure of claim 12, wherein the first reflector comprises an oxidizable layer, the oxidizable layer comprises an oxide-defined aperture and an oxidized portion, the oxidized portion surrounding the oxide-defined aperture.

16. A method for processing a semiconductor epitaxial structure, the method comprising:
providing a first reflector, a second reflector, and a plurality of layers located between the first reflector and the second reflector, wherein the second reflector includes an upper contact layer;
forming a mesa in the second reflector, wherein the upper contact layer is exposed after the forming the mesa; and
forming a plurality of trenches in the plurality of layers,
wherein the plurality of trenches is located around the mesa,
wherein each of the plurality of trenches is spatially separated from another trench by a region, the region including at least a portion of the upper contact layer.

17. The method of claim 16, further comprising:
oxidizing a region of an oxidizable layer, the oxidizable layer included in the first reflector or the second reflector, the region extending under a portion of the upper contact layer and under a portion of the mesa,
wherein the oxidizing creates an oxide-defined aperture.

18. The method of claim 16, further comprising:
depositing a dielectric layer overlying the upper contact layer;
etching a plurality of openings in the dielectric layer, the plurality of openings overlying the regions between the plurality of trenches; and
depositing a top metal contact, the top metal contact electrically connected to the upper contact layer at the plurality of openings.

19. The method of claim 16, further comprising:
depositing a dielectric layer overlying the upper contact layer;
etching a plurality of openings in the dielectric layer, the plurality of openings overlying portions of a lower contact layer, the lower contact layer included in the first reflector; and
depositing a lower metal contact, the lower metal contact electrically connected to the lower contact layer at the plurality of openings.

20. The method of claim 16, further comprising:
processing a vertical-cavity surface-emitting laser (VCSEL) using the semiconductor epitaxial structure.
